(19) United States
(12) Patent Application Publication
(10) Pub. No.: US 2024/0412788 A1
(43) Pub. Date: Dec. 12, 2024

(54) 3D FLASH MEMORY AND OPERATION METHOD THEREOF

(71) Applicant: IUCF-HYU (Industry-University Cooperation Foundation Hanyang University), Seoul (KR)

(72) Inventor: Yun Heub SONG, Seoul (KR)

(21) Appl. No.: 18/702,810

(22) PCT Filed: Oct. 20, 2022
(86) PCT No.: PCT/KR2022/016015

§ 371 Date: Apr. 19, 2024

(30) Foreign Application Priority Data
Oct. 20, 2021 (KR) 10-2021-0140299
Dec. 22, 2021 (KR) 10-2021-0185211

(51) Int. Cl. G11C 16/16; G11C 16/12; G11C 16/34

(52) U.S. Cl. CPC G11C 16/16; G11C 16/12; G11C 16/3404

(57) ABSTRACT

Disclosed are a 3D flash memory and an operating method thereof.

### TECHNICAL FIELD

Embodiments described herein relate to a three-dimensional (3D) flash memory, and more particularly, relate to a technology for a 3D flash memory implementing multi-levels and an operating method thereof, and a technology for a circuit compensation method and system to improve cell characteristic deterioration due to an abnormal shape AS of a vertical channel structure in a 3D flash memory.

### BACKGROUND ART

A flash memory element may be an electrically-erasable-programmable read only memory (EEPROM) that is electrically erasable and programmable by electrically controlling the input and output of data by Fowler-Nordheim tunneling or hot electron injection, and may be commonly used in computers, digital cameras, MP3 players, game systems, memory sticks, and the like.

In the flash memory element, it is required to increase the degree of integration to satisfy the excellent performance and a low price demanded by consumers. Accordingly, a 3D structure in which memory cell transistors are arranged in a vertical direction to form a cell string has been proposed.

As the 3D flash memory becomes more advanced in recent years, the integration of the 3D flash memory is facing difficult process problems. Accordingly, a method, which reduces a memory cell threshold voltage window for each state, such as a quad level cell (QLC) has been proposed for multi-levels.

Referring to FIG. 1 for describing the conventional QLC method, the QLC method may implement 16 states of 4 bits in one memory cell. For example, the QLC method may implement, in one memory cell, a first state Q0 representing data of “1111”, a second state Q1 representing data of “1110”, a third state Q2 representing data of “1101”, a fourth state Q3 representing data of “1100”, a fifth state Q4 representing data of “1011”, a sixth state Q5 representing data of “1010”, a seventh state Q6 representing data of “1001”, an eighth state Q7 representing data of “1000”, a ninth state Q8 representing data of “0111”, a tenth state Q9 representing data of “0110”, an eleventh state Q10 representing data of “0101”, a twelfth state Q11 representing data of “0100”, a thirteenth state Q12 representing data of “0011”, a fourteenth state Q13 representing data of “0010”, a fifteenth state Q14 representing data of “0001”, and a sixteenth state Q15 representing data of “0000”.

Due to the limitations of current cell operation technology, the conventional multi-level technology is difficult to implement multi-level in a method better than the QLC method.

Moreover, as the vertical channel structure, which is a memory cell string, becomes more advanced in the conventional 3D flash memory, the vertical channel structure may have an abnormal shape such as a spike. The abnormal shape, such as a spike, may cause changes in memory cell characteristics, thereby deteriorating memory reliability, accelerating pass voltage disturbances during program and read operations, and reducing a channel current.

Accordingly, there is a need to propose a technology for improving the deterioration of cell characteristics due to the abnormal shape of the vertical channel structure.

### DETAILED DESCRIPTION OF THE INVENTION

### Technical Problem

In an embodiment, a 3D flash memory for implementing multi-levels in a method better than a conventional QLC method, and an operating method thereof are proposed.

Moreover, in an embodiment, a method and a system for improving the deterioration of cell characteristics due to the abnormal shape of a vertical channel structure through circuit compensation are proposed to solve problems such as deteriorating memory reliability, accelerating pass voltage disturbances during program and read operations, and reducing a channel current.

In particular, in an embodiment, a method and a system for performing circuit compensation in different ways based on whether at least one memory cell, in which an abnormal shape occurs, is a selected memory cell that is the target of a program operation, are proposed.

However, the technical problems to be solved by the present disclosure are not limited to the above problems, and may be variously expanded without departing from the technical spirit and scope of the present disclosure.

### Technical Solution

According to an embodiment, a multi-level implementing method in a 3D flash memory may include securing a threshold voltage distribution region by narrowing a distribution of an erase threshold voltage during an erase operation of the 3D flash memory, and setting multi-level program threshold voltages in the secured threshold voltage distribution region.

According to an aspect, the securing may include applying an initial erase voltage to a selected word line corresponding to a memory cell that is a target of the erase operation among a plurality of word lines included in the 3D flash memory, applying a read voltage to the selected word line, and applying an additional erase voltage to the selected word line.

According to another aspect, the applying of the read voltage and the applying of the additional erase voltage may be sequentially repeated at least once or more.

According to still another embodiment, the additional erase voltage may decrease as the applying of the read voltage and the applying of the additional erase voltage are sequentially repeated.

According to yet another embodiment, the additional erase voltage may have a value smaller than the initial erase voltage.

According to an embodiment, a circuit compensating method for improving cell characteristic deterioration caused by an abnormal shape of a vertical channel structure, in a 3D flash memory including word lines formed to extend in a horizontal direction and spaced in a vertical direction, and vertical channel structures configured to penetrate the word lines and formed to extend in the vertical direction, each of the vertical channel structures including a vertical channel pattern formed to extend in the vertical direction and data storage patterns formed in contact with an outer sidewall of the vertical channel pattern, and each of the vertical channel structures constituting memory cells corresponding to the word lines may include monitoring a threshold voltage characteristic of each of the memory cells, identifying at least one memory cell, in which an abnormal shape occurs, from among the memory cells based on the threshold voltage characteristic of each of the memory cells by using a database configured to predict a relationship between an abnormal shape of the vertical channel structure and the threshold voltage characteristic, and distinguishing between a case where the at least one memory cell is a selected memory cell that is a target of a program operation, and a case where the at least one memory cell is an unselected memory cell excluding the selected memory cell among the memory cells, and performing circuit compensation.

According to an aspect, the performing may include distinguishing between the case, where the at least one memory cell is the selected memory cell, and the case where the at least one memory cell is the unselected memory cell, and controlling a voltage applied in the program operation or a voltage applied in a read operation on the selected memory cell.

According to another aspect, the controlling may include controlling the voltage applied in the program operation or the voltage applied in the read operation on the selected memory cell such that the at least one memory cell has a threshold voltage characteristic the same as the threshold voltage characteristic of another memory cell in which the abnormal shape does not occur.

According to still another aspect, when the at least one memory cell is the selected memory cell, the controlling may include at least one of decreasing a program voltage applied to the selected memory cell during the program operation, or increasing a bit line voltage applied to a bit line of a vertical channel structure including the selected memory cell during the program operation.

According to yet another aspect, when the at least one memory cell is the selected memory cell, the controlling may include at least one of increasing a sensing voltage applied to the selected memory cell during the read operation on the selected memory cell, or increasing a bit line voltage applied to a bit line of a vertical channel structure including the selected memory cell during the read operation.

According to yet another aspect, when the at least one memory cell is the unselected memory cell, the controlling may include decreasing a pass voltage applied to the at least one memory cell during the program operation.

According to yet another aspect, when the at least one memory cell is the unselected memory cell, the controlling may include increasing a pass voltage applied to the at least one memory cell during the read operation on the selected memory cell.

According to yet another aspect, the threshold voltage characteristic may include a threshold voltage value of each of the memory cells and a cell current value of each of the memory cells.

According to an embodiment, a circuit compensating system for improving cell characteristic deterioration caused by an abnormal shape of a vertical channel structure, in a 3D flash memory including word lines formed to extend in a horizontal direction and spaced in a vertical direction, and vertical channel structures configured to penetrate the word lines and formed to extend in the vertical direction, wherein each of the vertical channel structures includes a vertical channel pattern formed to extend in the vertical direction and data storage patterns formed in contact with an outer sidewall of the vertical channel pattern, and each of the vertical channel structures constitutes memory cells corresponding to the word lines may include a database built and maintained to predict a relationship between an abnormal shape of the vertical channel structure and a threshold voltage characteristic, a monitoring unit that monitors a threshold voltage characteristic of each of the memory cells, a check unit that identifies at least one memory cell, in which an abnormal shape occurs, from among the memory cells based on the threshold voltage characteristic of each of the memory cells by using the database, and a compensation unit that distinguishes between a case where the at least one memory cell is a selected memory cell that is a target of a program operation, and a case where the at least one memory cell is an unselected memory cell excluding the selected memory cell among the memory cells, and performs circuit compensation.

### Advantageous Effects of the Invention

In an embodiment, a 3D flash memory for implementing multi-levels in a method better than a conventional QLC method, and an operating method thereof may be proposed.

In an embodiment, problems such as deteriorating memory reliability, accelerating pass voltage disturbances during program and read operations, and reducing a channel current may be solved by proposing a method and a system for improving the deterioration of cell characteristics caused by the abnormal shape of the vertical channel structure through circuit compensation.

In particular, in an embodiment, a method and a system for performing circuit compensation in different ways based on whether at least one memory cell, in which an abnormal shape occurs, is a selected memory cell that is the target of a program operation, may be proposed.

However, the effects of the present disclosure are not limited to the effects, and may be variously expanded without departing from the spirit and scope of the present disclosure.

### DESCRIPTION OF THE DRAWINGS

FIG. 1 is a conceptual diagram for describing a conventional QLC method.

FIG. 2 is a flowchart showing a multi-level implementing method, according to an embodiment.

FIG. 3 is a conceptual diagram for describing step S220 shown in FIG. 2.

FIG. 4 is a flowchart showing detailed steps of step S220 shown in FIG. 2.

FIGS. 5 to 7 are conceptual diagrams for describing steps S410 to S430 shown in FIG. 4.

FIG. 8 is a simplified circuit diagram showing an array of a 3D flash memory, according to an embodiment.

FIG. 9 is a plan view showing a structure of a 3D flash memory, according to an embodiment.

FIG. 10 is a cross-sectional view illustrating a structure of a 3D flash memory, according to an embodiment, and corresponds to a cross-section taken along line A-A′ of FIG. 8.

FIG. 11 is a flowchart illustrating a circuit compensating method for improving cell characteristic deterioration caused by an abnormal shape of a vertical channel structure, according to an embodiment.

FIG. 12 is a block diagram showing a circuit compensating system that performs the circuit compensating method shown in FIG. 11.

FIGS. 13A and 13B are diagrams for describing that an abnormal shape occurs in a vertical channel structure in the 3D flash memory shown in FIG. 9.

FIGS. 14A to 14D are diagrams for describing that circuit compensation is performed when a memory cell in which an abnormal shape occurs is a selected memory cell that is the target of a program operation.

FIGS. 15A and 15B are diagrams for describing that a circuit compensating method is performed when a memory cell in which an abnormal shape occurs is an unselected memory cell.

### BEST MODE

Hereinafter, a description will be given in detail for embodiments of the present disclosure with reference to the following drawings. However, the present disclosure are not limited or restricted by the embodiments. Further, the same reference signs/numerals in the drawings denote the same members.

Furthermore, the terminologies used herein are used to properly express the embodiments of the present disclosure, and may be changed according to the intentions of a viewer or the manager or the custom in the field to which the present disclosure pertains. Therefore, definition of the terminologies should be made according to the overall disclosure set forth herein. For example, in the specification, the singular forms include plural forms unless particularly mentioned. Furthermore, the terminologies “comprises” and/or “comprising” used herein does not exclude presence or addition of one or more other components, steps, operations, and/or elements in addition to the aforementioned components, steps, operations, and/or elements. Moreover, the terminologies such as first, second, etc. and the like used in this specification to describe various areas, directions, shapes, and the like, these areas, directions, and shapes should not be limited by these terminologies. These terminologies are only used to distinguish one region, direction, or shape from another region, direction, or shape. Accordingly, a portion referred to as the first part in an embodiment may be referred to as the second part in another embodiment.

Moreover, it should be understood that various embodiments of the present disclosure are not necessarily mutually exclusive although being different from each other. For example, specific shapes, structures, and characteristics described herein may be implemented in other embodiments without departing from the spirit and scope of the present disclosure in relation to an embodiment. Besides, it should be understood that the location, arrangement, or configuration of individual components in each of presented categories of an embodiment may be changed without departing from the spirit and scope of the present disclosure.

Hereinafter, a 3D flash memory that implements multi-levels in a method better than a conventional QLC method and an operating method thereof are described with reference to drawings.

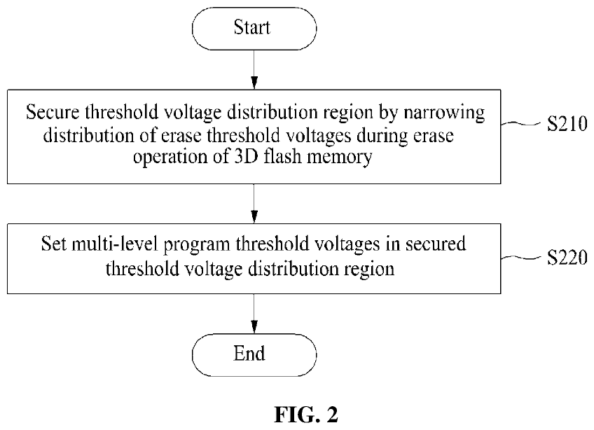

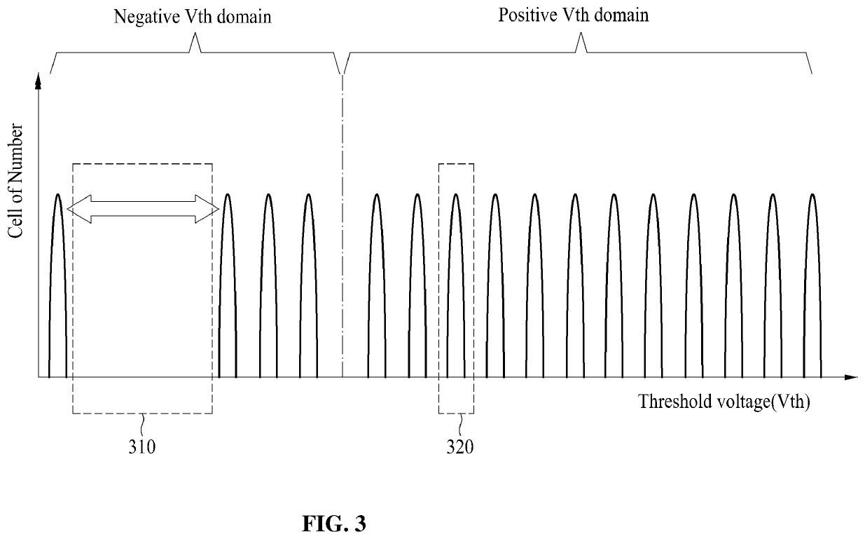

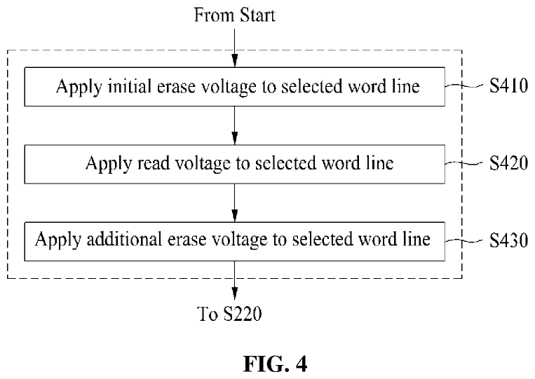

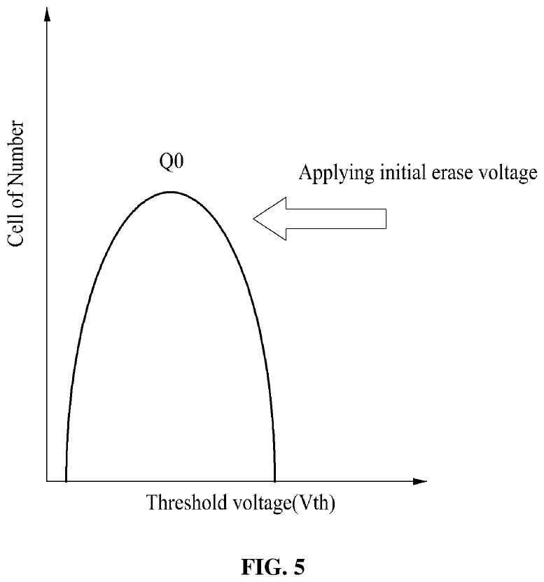

FIG. 2 is a flowchart showing a multi-level implementing method, according to an embodiment. FIG. 3 is a conceptual diagram for describing step S220 shown in FIG. 2. FIG. 4 is a flowchart showing detailed steps of step S220 shown in FIG. 2. FIGS. 5 to 7 are conceptual diagrams for describing steps S410 to S430 shown in FIG. 4.

It is assumed that a multi-level implementing method described below is performed by a 3D flash memory of a structure that is previously known. For example, the multi-level implementing method may be performed by the 3D flash memory of a structure including word lines and interlayer insulating layers, which form to extend in a horizontal direction and are alternately stacked in a vertical direction; and vertical channel structures (each of the vertical channel structures includes a vertical channel pattern formed to extend in the vertical direction, and a data storage pattern formed to contact an outer sidewall of the vertical channel pattern) that form to extend in a vertical direction and penetrate the word lines and the interlayer insulating layers. Accordingly, the multi-level implementing method described below refers to an operating method of the 3D flash memory for implementing multi-levels.

Referring to FIG. 2, in step S210, the 3D flash memory may secure a threshold voltage distribution region by narrowing the distribution of erase threshold voltages during an erase operation of the 3D flash memory.

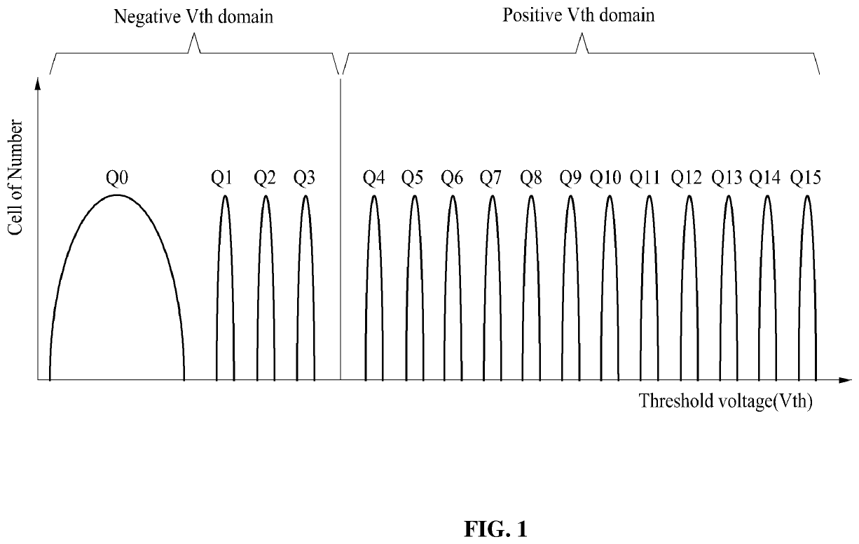

Because the first state Q0, which represents data of “1111”, from among states implemented in one memory cell needs to support a block erase operation in the conventional QLC method as shown in FIG. 1, the 3D flash memory basically has a very wide distribution. Accordingly, as shown in FIG. 3, in step S210, the 3D flash memory according to an embodiment may secure a threshold voltage distribution region 310 by narrowing the distribution of erase threshold voltages compared to the conventional QLC method. Hereinafter, narrowing the distribution of erase threshold voltages means narrowing the distribution of erase threshold voltages to a level of the distribution of program threshold voltages.

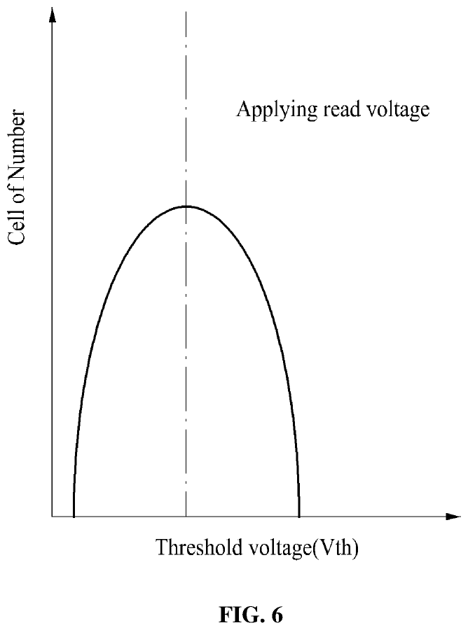

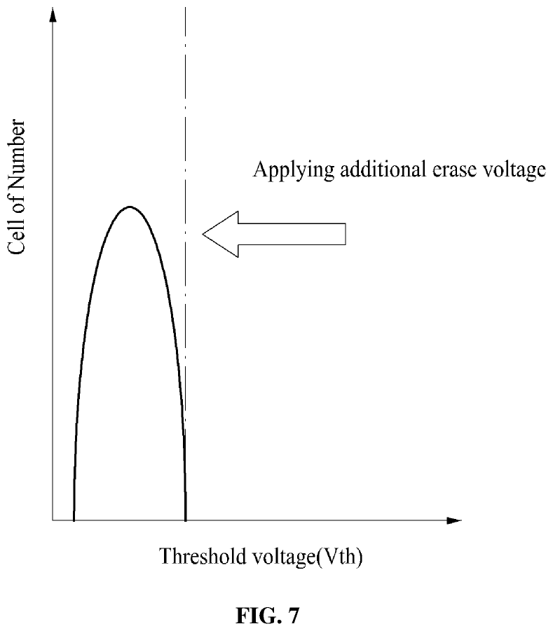

As such, obtaining the threshold voltage distribution region 310 in step S210 may be performed through steps S410 to S430 illustrated in FIG. 4. Referring to FIG. 4 in more detail, the 3D flash memory may perform step S210 of securing the threshold voltage distribution region 310, by performing step S410 of applying an initial erase voltage V_{erase 1} to a selected word line corresponding to a memory cell that is the target of the erase operation among the plurality of word lines as shown in FIG. 5, step S420 of applying a read voltage V_{verify} to the selected word line as shown in FIG. 6, and step S430 of applying additional erase voltages V_{erase 2}, V_{erase 3}, . . . , V_{erase n} to the selected word line as shown in FIG. 7.

In this case, step S420 and step S430 may be sequentially repeated at least once or more. For example, after the initial erase voltage V_{erase 1} is applied by performing step S410, the 3D flash memory may narrow the distribution of erase threshold voltages to half of the distribution level of erase threshold voltages when the initial erase voltage V_{erase 1} is applied, by applying the read voltage V_{verify} to the selected word line in step S420, and applying the additional erase voltage V_{erase 2} to the selected word line in step S430. Afterward, the 3D flash memory may narrow the distribution of erase threshold voltages to half of the distribution level of erase threshold voltages narrowed as the additional erase voltage V_{erase 2} is applied, by applying the read voltage V_{verify} to the selected word line once again in step S420, and applying the additional erase voltage V_{erase 3} to the selected word line in step S430.

As such, step S420 and step S430 may be sequentially repeated until the final distribution of erase threshold voltages is narrowed to the level of a distribution 320 of program threshold voltages.

Here, the additional erase voltage may decrease as step S420 and step S430 are sequentially repeated. For example, the additional erase voltage V_{erase 3} applied in step S430 performed next may have a more reduced value than the additional erase voltage V_{erase 2} applied in step S430 performed for the first time.

Moreover, the additional erase voltage may have a value smaller than the initial erase voltage applied in step S410.

In other words, step S210 may be performed in reverse of an incremental step pulse program (ISPP) method.

In step S220, the 3D flash memory may set multi-level program threshold voltages in the secured threshold voltage distribution region.

Likewise, the 3D flash memory according to an embodiment may set multi-level program threshold voltages in the threshold voltage distribution region secured by narrowing the distribution of erase threshold voltage compared with the conventional QLC method, thereby implementing more states of bits in one memory cell compared with the conventional QLC method of implementing 16 states of 4 bits in one memory cell.

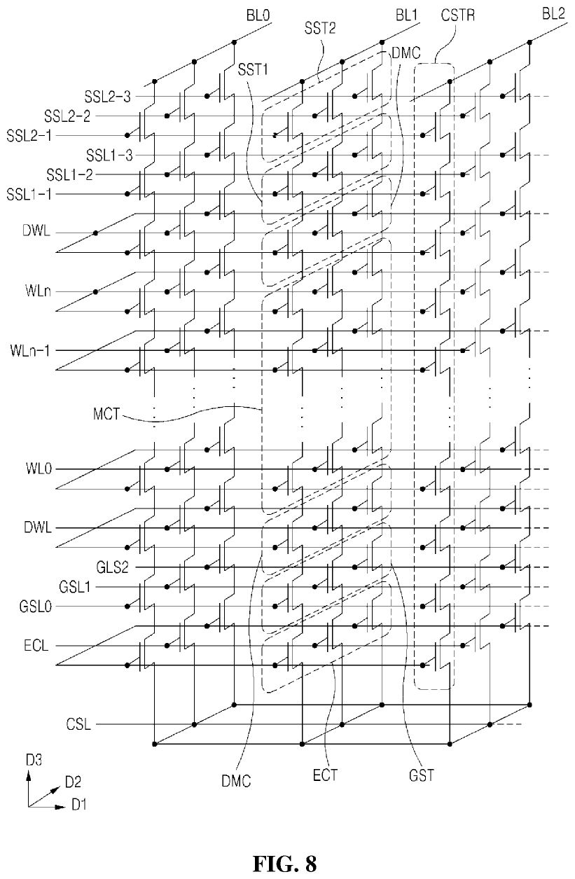

FIG. 8 is a simplified circuit diagram showing an array of a 3D flash memory, according to an embodiment.

Referring to FIG. 8, an array of 3D flash memory according to an embodiment includes a common source line CSL, a plurality of bit lines BL0, BL1, and BL2, and a plurality of cell strings CSTR interposed between the common source line CSL and the bit lines BL0, BL1, and BL2.

The bit lines BL0, BL1, and BL2 may be spaced from each other in a first direction D1 while being formed to extend in a second direction D2, and may be arranged two-dimensionally. Here, the first direction D1, the second direction D2, and a third direction D3 are orthogonal to each other and may form a Cartesian coordinate system defined by the X, Y, and Z axes.

The plurality of cell strings CSTR may be connected in parallel to each of the bit lines BL0, BL1, and BL2. The cell strings CSTR may be connected to the common source line CSL while being provided between the bit lines BL0, BL1, and BL2 and one common source line CSL. In this case, there may be the plurality of common source lines CSL. The plurality of common source lines CSL may be arranged two-dimensionally and may be spaced from each other in the second direction D2 while being formed to extend in the first direction D1. Voltages, which are electrically the same as each other, may be applied to the plurality of common source lines CSL. However, an embodiment is not limited thereto. For example, different voltages may be applied to the plurality of common source lines CSL by controlling the plurality of common source lines CSL electrically and independently.

The cell strings CSTR may be arranged to be spaced from each other in the second direction D2 for each bit line while being formed to extend in the third direction D3. According to an embodiment, each of the cell strings CSTR may be composed of a ground selection transistor GST connected to the common source line CSL, first and second string selection transistors SST1 and SST2 connected in series to the bit lines BL0, BL1, and BL2, memory cell transistors MCT, which are connected in series while being placed between the ground selection transistor GST and the first and second string selection transistors SST1 and SST2, and an erase control transistor ECT. Furthermore, each of the memory cell transistors MCT may include a data storage element.

For example, each of the cell strings CSTR may include the first and second string selection transistors SST1 and SST2 connected in series to each other. The second string selection transistor SST2 may be connected to one of the bit lines BL0, BL1, and BL2. However, an embodiment is not limited thereto. For example, each of the cell strings CSTR may include one string selection transistor. For another example, similarly to the first and second string selection transistors SST1 and SST2, the ground selection transistor GST in each of the cell strings CSTR may be composed of a plurality of MOS transistors connected in series to each other.

The single cell string CSTR may be composed of the plurality of memory cell transistors MCT with distances from the common source lines CSL different from each other. In other words, the memory cell transistors MCT may be connected in series to each other while being placed between the first string selection transistor SST1 and the ground selection transistor GST in the third direction D3. The erase control transistor ECT may be connected between the ground selection transistor GST and the common source lines CSL. Each of the cell strings CSTR may further include dummy cell transistors DMC connected between the first string selection transistor SST1 and the uppermost one of the memory cell transistors MCT and between the ground selection transistor GST and the lowermost one of the memory cell transistors MCT.

According to an embodiment, the first string selection transistor SST1 may be controlled by first string selection lines SSL1-1, SSL1-2, and SSL1-3. The second string selection transistor SST2 may be controlled by second string selection lines SSL2-1, SSL2-2, and SSL2-3. The memory cell transistors MCT may be controlled by a plurality of word lines WL0 to WLn. The dummy cell transistors DMC may be controlled by a dummy word line DWL. The ground selection transistor GST may be controlled by ground selection lines GSL0, GSL1, and GSL2. The erase control transistor ECT may be controlled by an erase control line ECL. There may be the plurality of erase control transistors ECT. The common source lines CSL may be connected in common to sources of the erase control transistors ECT.

The gate electrodes of the memory cell transistors MCT provided at substantially the same distance from the common source lines CSL may be commonly connected to one of the word lines WL0 to WLn and DWL and may be in an equipotential state. However, an embodiment is not limited thereto. For example, even though the gate electrodes of the memory cell transistors MCT are provided at substantially the same level from the common source lines CSL, gate electrodes provided to different rows or columns may also be controlled independently.

The ground selection lines GSL0, GSL1, and GSL2, the first string selection lines SSL1-1, SSL1-2, and SSL1-3 and the second string selection lines SSL2-1, SSL2-2, and SSL2-3 may extend in the first direction D1, may be spaced from each other in the second direction D2, and may be arranged two-dimensionally. The ground selection lines GSL0, GSL1, and GSL2, the first string selection lines SSL1-1, SSL1-2, and SSL1-3, and the second string selection lines SSL2-1, SSL2-2, and SSL2-3, which are provided at substantially the same level from the common source lines CSL may be electrically isolated from each other. Moreover, the erase control transistors ECT of the different cell strings CSTR may be controlled by the common erase control line ECL. The erase control transistors ECT may generate gate induced drain leakage (hereinafter, referred to as “GIDL”) during an erase operation of the memory cell array. In some embodiments, during the erase operation of the memory cell array, an erase voltage may be applied to the bit lines BL0, BL1, and BL2 and/or the common source lines CSL, and a gate induced leakage current may occur in a string selection transistor SST and/or the erase control transistors ECT.

The string selection line SSL described above may be expressed as an upper selection line USL, and the ground selection line GSL described above may be expressed as a lower selection line LSL.

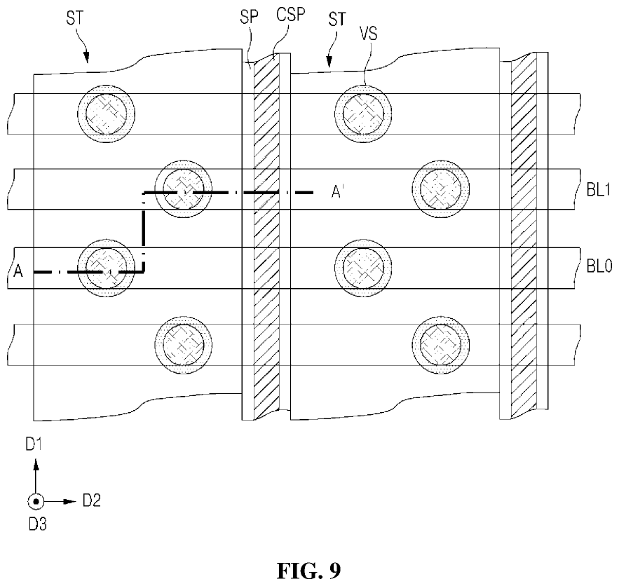

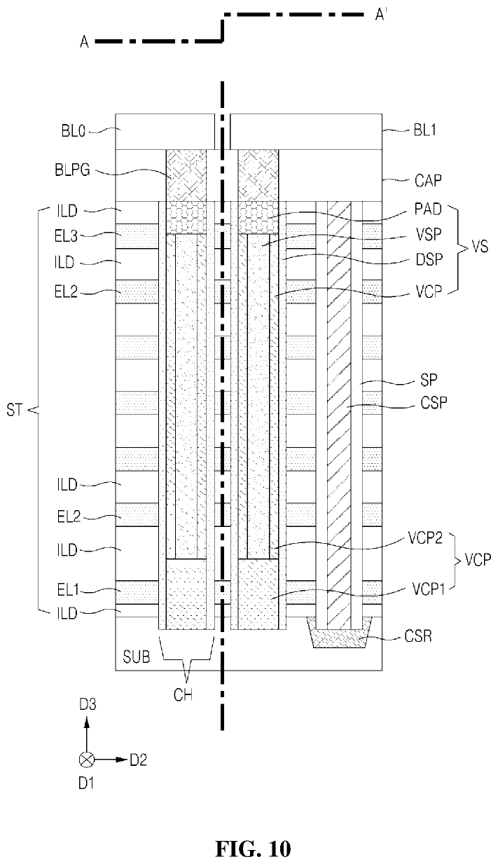

FIG. 9 is a plan view showing a structure of a 3D flash memory, according to an embodiment. FIG. 10 is a cross-sectional view illustrating a structure of a 3D flash memory, according to an embodiment, and corresponds to a cross-section taken along line A-A′ of FIG. 8.

Referring to FIGS. 9 and 10, a substrate SUB may be a semiconductor substrate such as a silicon substrate, a silicon-germanium substrate, a germanium substrate, or a monocrystalline epitaxial layer grown on a monocrystalline silicon substrate. The substrate SUB may be doped with first conductive impurities (e.g., P-type impurities).

Stacked structures ST may be placed on the substrate SUB. The stacked structures ST may be arranged two-dimensionally in the second direction D2 while being formed to extend in the first direction D1. Moreover, the stacked structures ST may be spaced from each other in the second direction D2.

Each of the stacked structures ST may include gate electrodes EL1, EL2, and EL3, and interlayer insulating layers ILD, which are alternately stacked in a vertical direction (e.g., the third direction D3) perpendicular to the top surface of the substrate SUB. The stacked structures ST may have a substantially flat top surface. That is, the top surface of the stacked structures ST may be parallel to the top surface of the substrate SUB. Hereinafter, the vertical direction means the third direction D3 or a direction opposite to the third direction D3.

Returning to FIG. 8, each of the gate electrodes EL1, EL2, and EL3 may be one of the erase control line ECL, the ground selection lines GSL0, GSL1, and GSL2, the word lines WL0 to WLn and DWL, the first string selection lines SSL1-1, SSL1-2, and SSL1-3, and the second string selection lines SSL2-1, SSL2-2, and SSL2-3, which are sequentially stacked on the substrate SUB.

Each of the gate electrodes EL1, EL2, and EL3 may have substantially the same thickness in the third direction D3 while being formed to extend in the first direction D1. Hereinafter, the thickness means a thickness in the third direction D3. Each of the gate electrodes EL1, EL2, and EL3 may be formed of a conductive material. For example, each of the gate electrodes EL1, EL2, and EL3 may include at least one selected from a doped semiconductor (e.g., doped silicon), metal (e.g., tungsten W, copper Cu, aluminum Al, titanium Ti, tantalum Ta, molybdenum Mo, ruthenium Ru, gold Au, or the like), or conductive metal nitride (e.g., titanium nitride, tantalum nitride, or the like). Each of the gate electrodes EL1, EL2, and EL3 may include at least one of all metal materials capable of being formed by using ALD in addition to the above-described metal material.

In more detail, the gate electrodes EL1, EL2, and EL3 may include the first gate electrode EL1 located at the bottom, the third gate electrode EL3 located at the top, and the plurality of second gate electrodes EL2 between the first gate electrode EL1 and the third gate electrode EL3. It is shown and described that there are the one first gate electrode EL1 and the one third gate electrode EL3. However, an embodiment is not limited thereto. For example, when necessary, there are the plurality of first gate electrodes EL1 and the plurality of third gate electrodes EL3. The first gate electrode EL1 may correspond to one of the ground selection lines GSL0, GSL1, and GSL2 shown in FIG. 8. The second gate electrode EL2 may correspond to one of the word lines WL0 to WLn and DWL shown in FIG. 8. The third gate electrode EL3 may correspond to one of the first string selection lines SSL1-1, SSL1-2, and SSL1-3 shown in FIG. 8, or one of the second string selection lines SSL2-1, SSL2-2, and SSL2-3.

Although not shown, an end portion of each of the stacked structures ST may have a stepwise structure in the first direction D1. In more detail, as the gate electrodes EL1, EL2, and EL3 of the stacked structures ST move away from the substrate SUB, the length in the first direction D1 may decrease. The third gate electrode EL3 may have the smallest length in the first direction D1, and may have the greatest distance from the substrate SUB in the third direction D3. The first gate electrode EL1 may have the greatest length in the first direction D1, and may have the smallest distance from the substrate SUB in the third direction D3. As each of the stacked structures ST move away from the outer-most one of vertical channel structures VS described later, the thickness of each of the stacked structures ST may decrease due to the stepwise structure, and sidewalls of the gate electrodes EL1, EL2, and EL3 may be spaced from each other at specific intervals in the first direction D1, when viewed from above a plane.

The interlayer insulating layers ILD may have different thicknesses from each other. For example, the lowermost one and the uppermost one of the interlayer insulating layers ILD may have a smaller thickness than the other interlayer insulating layers ILD. However, an embodiment is not limited thereto. For example, thicknesses of the interlayer insulating layers ILD may be different from each other depending on characteristics of the semiconductor device, or may be set to the same thickness as each other. The interlayer insulating layers ILD may be formed of an insulating material for insulation between the gate electrodes EL1, EL2, and EL3. For example, the interlayer insulating layers ILD may be formed of silicon oxide.

Above, it is described that the interlayer insulating layers ILD are placed between the stacked structures ST. However, air gaps instead of the interlayer insulating layers ILD may be placed between the stacked structures ST. In this case, like the interlayer insulating layers ILD, the air gaps and the gate electrodes EL1, EL2, and EL3 may be alternately placed for the insulation between the gate electrodes EL1, EL2, and EL3.

A plurality of channel holes CH penetrating a portion of the stacked structures ST and the substrate SUB may be provided. The vertical channel structures VS may be provided within the channel holes CH. The vertical channel structures VS may be the plurality of cell strings CSTR shown in FIG. 8 and may be formed to extend in the third direction D3 while being connected to the substrate SUB. Connecting the vertical channel structures VS to the substrate SUB may be achieved by embedding a portion of each of the vertical channel structures VS inside the substrate SUB. However, an embodiment is not limited thereto. For example, this may also be achieved by contacting the lower surface of the vertical channel structures VS with the top surface of the substrate SUB. When a part of each of the vertical channel structures VS is embedded inside the substrate SUB, the bottom surface of the vertical channel structures VS may be located to be lower than the top surface of the substrate SUB.

There may be a plurality of columns of the vertical channel structures VS penetrating one of the stacked structures ST. For example, as shown in FIG. 10, two columns of the vertical channel structures VS may penetrate one of the stacked structures ST. However, an embodiment is not limited thereto. For example, three or more columns of the vertical channel structures VS may penetrate one of the stacked structures ST. In a pair of columns adjacent to each other, the vertical channel structures VS corresponding to one column may be shifted from the vertical channel structures VS corresponding to another column adjacent thereto in the first direction D1. When viewed from above a plane, the vertical channel structures VS may be arranged in a zigzag manner in the first direction D1. However, an embodiment is not limited thereto. For example, the vertical channel structures VS may form an array arranged side by side in rows and columns.

Each of the vertical channel structures VS may be formed to extend from the substrate SUB in the third direction D3. In the drawing, it is shown that each of the vertical channel structures VS has a pillar shape, in which widths of the upper end and the lower end are the same as each other. However an embodiment is not limited thereto. Each of the vertical channel structures VS may have a shape in which the width in the first direction D1 and the width in the second direction D2 increase depending on the progress in the third direction D3. The reason is that the widths in the first direction D1 and the second direction D2 are reduced depending on the progress in a direction opposite to the third direction D3 when the channel holes CH are etched. The top surface of each of the vertical channel structures VS may have a circular shape, an oval shape, a square shape, or a bar shape.

Each of the vertical channel structures VS may include data storage patterns DSP, a vertical channel pattern VCP, a vertical semiconductor pattern VSP, and a conductive pad PAD. In each of the vertical channel structures VS, the vertical channel pattern VCP may have a pipe shape, of which the bottom end is closed, or a macaroni shape. The vertical semiconductor pattern VSP may fill the space surrounded by the vertical channel pattern VCP and the conductive pad PAD.

The data storage patterns DSP may externally contact the sidewall of the gate electrodes EL1, EL2, and EL3 by contacting the outer sidewall of the vertical channel pattern VCP and being spaced from each other to correspond to the gate electrodes EL1, EL2, and EL3. Accordingly, together with regions, which correspond to the second gate electrodes EL2 and which is within the vertical channel pattern VCP, those corresponding to the second gate electrodes EL2 among the data storage patterns DSP may be formed as memory cells in each of which a memory operation (a program operation, a read operation, or an erase operation) is performed by the voltage applied through the second gate electrodes EL2. The memory cells correspond to the memory cell transistors MCT shown in FIG. 8. In other words, each of the data storage patterns DSP may serve as data storage in a 3D flash memory by trapping charges or holes by voltage applied through the second gate electrodes EL2 or maintaining states (e.g., polarization states of charges) of the charges. For example, as the data storage patterns DSP, a charge storage film of ONO (tunnel oxide film (oxide)-charge storage film (nitride)-blocking oxide film (oxide)) may be used, or a ferroelectric layer may be used. Each of these data storage patterns DSP may represent a binary data value or a multi-level data value by changing trapped charges or holes or may represent a binary data value or a multi-level data value by changing the state of charges.

The vertical channel pattern VCP may contact the inner sidewall of the data storage patterns DSP and may be formed to extend in a vertical direction (e.g., the third direction D3) through the gate electrodes EL1, EL2, and EL3. The vertical channel pattern VCP may include a first portion VCP1 and a second portion VCP2 placed on the first portion VCP1.

The first portion VCP1 of the vertical channel pattern VCP may be provided to a lower portion of each of the channel holes CH and may be in contact with the substrate SUB. The first portion VCP1 of the vertical channel pattern VCP may be used to block, suppress, or minimize a leakage current in each of the vertical channel structures VS, and/or may be used as an epitaxial pattern. For example, the thickness of the first portion VCP1 of the vertical channel pattern VCP may be greater than the thickness of the first gate electrode EL1. The sidewall of the first portion VCP1 of the vertical channel pattern VCP may be surrounded by the data storage patterns DSP. The top surface of the first portion VCP1 of the vertical channel pattern VCP may be located to be higher than the top surface of the first gate electrode EL1. In more detail, the top surface of the first portion VCP1 of the vertical channel pattern VCP may be located between the top surface of the first gate electrode EL1 and the bottom surface of the lowermost one of the second gate electrodes EL2. The bottom surface of the first portion VCP1 of the vertical channel pattern VCP may be located to be lower than the uppermost surface (i.e., the bottom surface of the lowermost one of the interlayer insulating layers ILD) of the substrate SUB. A portion of the first portion VCP1 of the vertical channel pattern VCP may overlap the first gate electrode EL1 in a horizontal direction. Hereinafter, the horizontal direction means an arbitrary direction extending on a plane in parallel with the first direction D1 and the second direction D2.

The second portion VCP2 of the vertical channel pattern VCP may extend from the top surface of the first portion VCP1 in the third direction D3. The second portion VCP2 of the vertical channel pattern VCP may be provided between the data storage patterns DSP and the vertical semiconductor pattern VSP, and may correspond to the second gate electrodes EL2. Accordingly, as described above, the second portion VCP2 of the vertical channel pattern VCP may form the memory cells together with the data storage patterns DSP.

The top surface of the second portion VCP2 of the vertical channel pattern VCP and the top surface of the vertical semiconductor pattern VSP may be formed of substantially the same surface. The top surface of the second portion VCP2 of the vertical channel pattern VCP may be located to be higher than the top surface of the uppermost one of the second gate electrodes EL2. In more detail, the top surface of the second portion VCP2 of the vertical channel pattern VCP may be located between the top surface and bottom surface of the third gate electrode EL3.

The vertical channel pattern VCP may be a component that delivers charges or holes to the data storage patterns DSP, and may be formed of monocrystalline silicon or polysilicon to form a channel by an applied voltage, or to boost the channel. However, an embodiment is not limited thereto. For example, the vertical channel pattern VCP may be formed of an oxide semiconductor material capable of blocking, suppressing, or minimizing a leakage current. For example, the vertical channel pattern VCP may be formed of a Group-IV semiconductor material or an oxide semiconductor material including at least one of In, Zn, or Ga with excellent leakage current characteristics. For example, the vertical channel pattern VCP may be formed of ZnOx-based materials including AZO, ZTO, IZO, ITO, IGZO, or Ag—ZnO. Accordingly, the vertical channel pattern VCP may block, suppress, or minimize the leakage current to the gate electrodes EL1, EL2, and EL3 or the substrate SUB, thereby improving the transistor characteristics of at least one of the gate electrodes EL1, EL2, and EL3, and, as a result, improving electrical characteristics (e.g., a threshold voltage distribution and the speed of a program/read operation) of the 3D flash memory.

The vertical semiconductor pattern VSP may be surrounded by the second portion VCP2 of the vertical channel pattern VCP. The top surface of the vertical semiconductor pattern VSP may contact the conductive pad PAD, and the bottom surface of the vertical semiconductor pattern VSP may contact the first portion VCP1 of the vertical channel pattern VCP. The vertical semiconductor pattern VSP may be spaced from the substrate SUB in the third direction D3. In other words, the vertical semiconductor pattern VSP may be electrically floated from the substrate SUB.

The vertical semiconductor pattern VSP may be formed of materials that aid in the diffusion of charges or holes in the vertical channel pattern VCP. In more detail, the vertical semiconductor pattern VSP may be formed of a material with excellent charge and hole mobility. For example, the vertical semiconductor pattern VSP may be formed of a semiconductor material doped with impurities, an intrinsic semiconductor material in a state where impurities are not doped, or a polycrystalline semiconductor material. For a more specific example, the vertical semiconductor pattern VSP may be formed of polysilicon doped with first conductive impurities (e.g., P-type impurities) the same as the substrate SUB. In other words, the vertical semiconductor pattern VSP may improve electrical characteristics of the 3D flash memory, thereby improving the speed of the memory operation.

Returning to FIG. 8, the vertical channel structures VS may correspond to channels of the erase control transistor ECT, the first and second string selection transistors SST1 and SST2, the ground selection transistor GST, and the memory cell transistors MCT.

The conductive pad PAD may be provided on the top surface of the second portion VCP2 of the vertical channel pattern VCP, and the top surface of the vertical semiconductor pattern VSP. The conductive pad PAD may be connected to an upper portion of the vertical channel pattern VCP and an upper portion of the vertical semiconductor pattern VSP. The sidewall of the conductive pad PAD may be surrounded by the data storage patterns DSP. The top surface of the conductive pad PAD and the top surface (i.e., the top surface of the uppermost one of the interlayer insulating layers ILD) of each of the stacked structures ST may be formed of substantially the same surface. The bottom surface of the conductive pad PAD may be located to be lower than the top surface of the third gate electrode EL3. In more detail, the bottom surface of the conductive pad PAD may be located between the top surface and the bottom surface of the third gate electrode EL3. That is, at least part of the conductive pad PAD may overlap the third gate electrode EL3 in the horizontal direction.

The conductive pad PAD may be formed of a semiconductor or conductive material doped with impurities. For example, the conductive pad PAD may be formed of a semiconductor material doped with impurities (more precisely, second conductive (e.g., N-type) impurities different from first conductive (e.g., P-type) impurities) different from those of the vertical semiconductor pattern VSP.

The conductive pad PAD may reduce the contact resistance between the vertical channel pattern VCP (or the vertical semiconductor pattern VSP) and a bit line BL to be described later.

Above, it is described that the vertical channel structures VS have a structure including the conductive pad PAD, but an embodiment is not limited thereto. For example, the vertical channel structures VS may have a structure excluding the conductive pad PAD. In this case, as the conductive pad PAD is omitted in the vertical channel structures VS, each of the vertical channel pattern VCP and the vertical semiconductor pattern VSP may be formed to extend in the third direction D3 such that the top surface (i.e., the top surface of the uppermost one of the interlayer insulating layers ILD) of each of the vertical channel pattern VCP and the vertical semiconductor pattern VSP and the top surface of each of the stacked structures ST may be formed of substantially the same surface. Moreover, in this case, a bit line contact plug BLPG to be described later may be directly connected to the vertical channel pattern VCP and may be electrically connected to the vertical channel pattern VCP, instead of being indirectly and electrically connected to the vertical channel pattern VCP through the conductive pad PAD.

Furthermore, it is described that the vertical semiconductor pattern VSP is included in the vertical channel structures VS. However, an embodiment is not limited thereto. For example, the vertical semiconductor pattern VSP may be omitted.

Besides, a structure in which the vertical channel pattern VCP includes the first portion VCP1 and the second portion VCP2 is described. An embodiment is not limited thereto. For example, in the structure, the first portion VCP1 may be excluded. For example, the vertical channel pattern VCP may be provided between the vertical semiconductor pattern VSP and a data storage pattern DSP, which are formed to extend up to the substrate SUB, and may be formed to extend up to the substrate SUB so as to contact the substrate SUB. In this case, the bottom surface of the vertical channel pattern VCP may be located to be lower than the uppermost surface (the bottom surface of the lowermost one of the interlayer insulating layers ILD) of the substrate SUB, and the top surface of the vertical channel pattern VCP and the top surface of the vertical semiconductor pattern VSP may be formed of substantially the same surface.

A separation trench TR extending in the first direction D1 may be provided between the stacked structures ST adjacent to each other. A common source region CSR may be provided inside the substrate SUB exposed by the separation trench TR. The common source region CSR may extend in the first direction D1 within the substrate SUB. The common source region CSR may be formed of a semiconductor material doped with second conductive impurities (e.g., N-type impurities). The common source region CSR may correspond to the common source line CSL in FIG. 8.

A common source plug CSP may be provided within the separation trench TR. The common source plug CSP may be connected to the common source region CSR. The top surface of the common source plug CSP and the top surface (i.e., the top surface of the uppermost one of the interlayer insulating layers ILD) of each of the stacked structures ST may be formed of substantially the same surface. The common source plug CSP may have a plate shape extending in the first direction D1 and the third direction D3. In the case, the common source plug CSP may have a shape in which the width in the second direction D2 increases depending on the progress in the third direction D3.

Insulating spacers SP may be interposed between the common source plug CSP and the stacked structures ST. The insulating spacers SP may be provided to be opposite to each other between the stacked structures ST adjacent to each other. For example, the insulating spacers SP may be formed of silicon oxide, silicon nitride, silicon oxynitride, or a low-k material with a low dielectric constant.

A capping insulating film CAP may be provided on the stacked structures ST, the vertical channel structures VS, and the common source plug CSP. The capping insulating film CAP may cover the top surface of the uppermost one of the interlayer insulating layers ILD, the top surface of the conductive pad PAD, and the top surface of the common source plug CSP. The capping insulating film CAP may be formed of an insulating material different from the interlayer insulating layers ILD. The bit line contact plug BLPG may be provided, which is electrically connected to the conductive pad PAD, inside the capping insulating film CAP. The bit line contact plug BLPG may have a shape in which the width in the first direction D1 and the second direction D2 increases depending on the progress in the third direction D3.

The bit line BL may be provided on the capping insulating film CAP and the bit line contact plug BLPG. The bit line BL may correspond to one of the plurality of bit lines BL0, BL1, and BL2 shown in FIG. 8, and may be formed of a conductive material to extend in the second direction D2. The conductive material forming the bit line BL may be the same material as the conductive material forming each of the gate electrodes EL1, EL2, and EL3 described above.

The bit line BL may be electrically connected to the vertical channel structures VS through the bit line contact plug BLPG. Here, the fact that the bit line BL is connected to the vertical channel structures VS may mean that it is connected to the vertical channel pattern VCP included in the vertical channel structures VS.

The 3D flash memory with this structure may perform a program operation, a read operation, and an erase operation based on a voltage applied to each of the cell strings CSTR, a voltage applied to the string selection line SSL, a voltage applied to each of the word lines WL0 to WLn, a voltage applied to the ground selection line GSL, and a voltage applied to the common source line CSL. For example, the 3D flash memory may perform the program operation by forming a channel in the vertical channel pattern VCP and delivering charges or holes to the data storage pattern DSP of a target memory cell based on the voltage applied to each of the cell strings CSTR, the voltage applied to the string selection line SSL, the voltage applied to each of the word lines WL0 to WLn, the voltage applied to the ground selection line GSL, and the voltage applied to the common source line CSL.

Moreover, the 3D flash memory according to an embodiment is not limited to the described structure, and may be implemented with various structures in each of which it is assumed that the vertical channel pattern VCP, the data storage pattern DSP, the gate electrodes EL1, EL2, and EL3, the bit line BL, and the common source line CSL are included, according to implementation examples.

Above, the 3D flash memory with the structure of including the vertical semiconductor pattern VSP is described. However, the 3D flash memory may have a structure of including a back gate BG while the vertical semiconductor pattern VSP is omitted. In this case, the back gate BG, which is further included in each of the vertical channel structures VS, may be formed to extend in the vertical direction (e.g., the third direction D3) while filling the internal space of the vertical channel pattern VCP. Hereinafter, the fact that the back gate BG fills the internal space of the vertical channel pattern VCP means that the back gate BG is included in the vertical channel pattern VCP in a state where at least one portion is surrounded by the vertical channel pattern VCP.

The back gate BG may be formed to contact the vertical channel pattern VCP while contacting at least one portion surrounded by the vertical channel pattern VCP, and to apply a voltage to the vertical channel pattern VCP for the memory operation. To this end, the back gate BG may be formed of a conductive material including at least one selected from a doped semiconductor (e.g., doped silicon), metal (e.g., tungsten W, copper Cu, aluminum Al, titanium Ti, tantalum Ta, molybdenum Mo, ruthenium Ru, gold Au, or the like), or conductive metal nitride (e.g., titanium nitride, tantalum nitride, or the like). The back gate BG may include at least one of all metal materials capable of being formed by using ALD in addition to the above-described metal material.

In this case, the back gate BG may be formed to extend in the third direction D3 from a level corresponding to the first gate electrode EL1 to a level corresponding to the second gate electrode EL2 within the vertical channel pattern VCP. In other words, the top surface of the back gate BG may be located to be higher than the top surface of the uppermost one of the second gate electrodes EL2. However, an embodiment is not limited thereto. For example, the back gate BG may be formed to extend in the third direction D3 to a level corresponding to the third gate electrode EL3 within the vertical channel pattern VCP.

According to implementation examples, the back gate BG may include a lower substrate that is in contact with the bottom surface of the back gate BG. Moreover, according to implementation examples, the back gate BG may be formed from the inside of the substrate SUB or may be formed from the upper portion of the substrate SUB.

As such, the back gate BG may be included in the vertical channel pattern VCP of each of the cell strings CSTR and may be electrically connected on a plane formed by the first direction D1 and the second direction D2. That is, the back gate BG may be commonly connected to the cell strings CSTR. In this case, the back gate BG of each of the cell strings CSTR may be collectively controlled such that the same voltage may be applied.

However, an embodiment is not limited thereto. For example, the back gate BG included in the vertical channel pattern VCP of each of the cell strings CSTR may be electrically connected to each other in the first direction D1 of FIG. 8. In this case, the back gate BG of each of the cell strings CSTR arranged in the second direction D2 may be electrically and independently controlled, and thus different voltages may be applied. The back gate BG of each of the cell strings CSTR arranged in the first direction D1 in FIG. 8 may be collectively controlled, and thus the same voltage may be applied.

Moreover, the back gate BG included in the vertical channel pattern VCP of each of the cell strings CSTR may be electrically connected to each other in the second direction D2 of FIG. 8. In this case, the back gate BG of each of the cell strings CSTR arranged in the first direction D1 may be electrically and independently controlled, and thus different voltages may be applied. The back gate BG of each of the cell strings CSTR arranged in the second direction D2 in FIG. 8 may be collectively controlled, and thus the same voltage may be applied.

The back gate BG may be prevented from directly contacting the vertical channel pattern VCP by placing an insulating film INS between the back gate BG and the vertical channel pattern VCP. The insulating film INS, like the interlayer insulating layers ILD, may be formed of an insulating material such as silicon oxide.

The back gate BG may be formed in a structure in which at least one portion is surrounded by the vertical channel pattern VCP. For example, a structure, in which the back gate BG and the insulating film INS are included in at least one portion of the vertical channel pattern VCP, or a structure of penetrating the vertical channel pattern VCP may be implemented.

The 3D flash memory with this structure may perform the program operation, the read operation, and the erase operation based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and a voltage applied to the back gate BG. For example, the 3D flash memory may perform the program operation by forming a channel in the vertical channel pattern VCP and delivering charges or holes to the data storage pattern DSP of a target memory cell based on the voltage applied to each of the cell strings CSTR, the voltage applied to the string selection line SSL, the voltage applied to each of the word lines WL0 to WLn, the voltage applied to the ground selection line GSL, the voltage applied to the common source line CSL, and a voltage applied to the back gate BG.

According to implementation examples, the 3D flash memory including a structure including the back gate BG may be implemented with various structures in each of which it is assumed that the vertical channel pattern VCP, the data storage pattern DSP, the back gate BG, the gate electrodes EL1, EL2, and EL3, the bit line BL, and the common source line CSL are included.

Below, a circuit compensating method and system for improving cell characteristic deterioration due to the abnormal shape AS of the vertical channel structure VS in the 3D flash memory of the above-described structure is described.

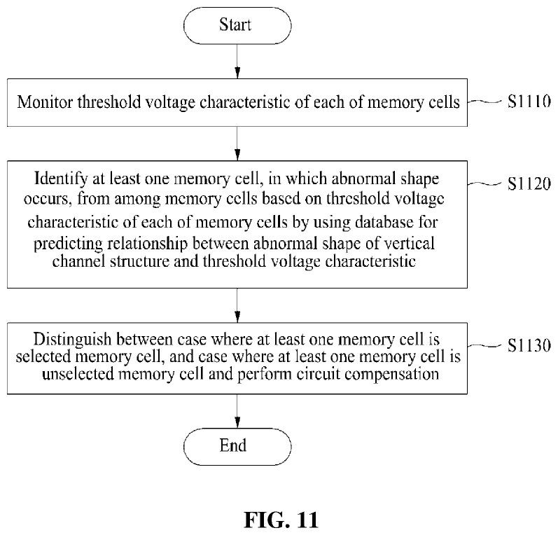

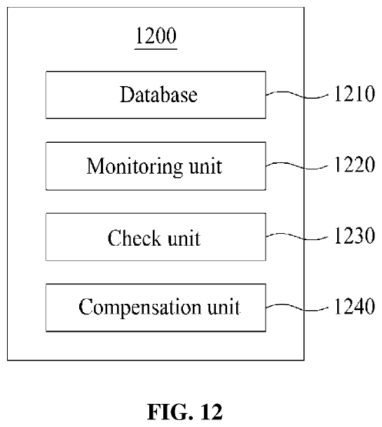

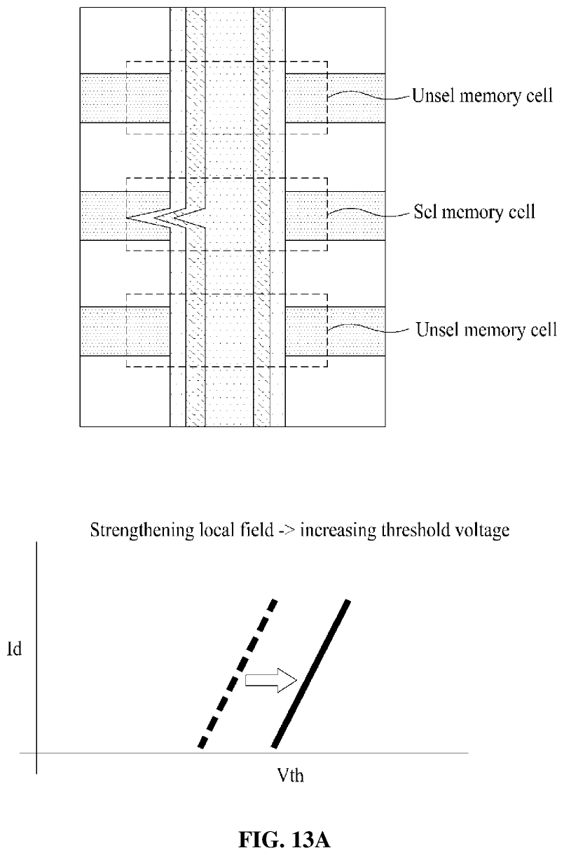

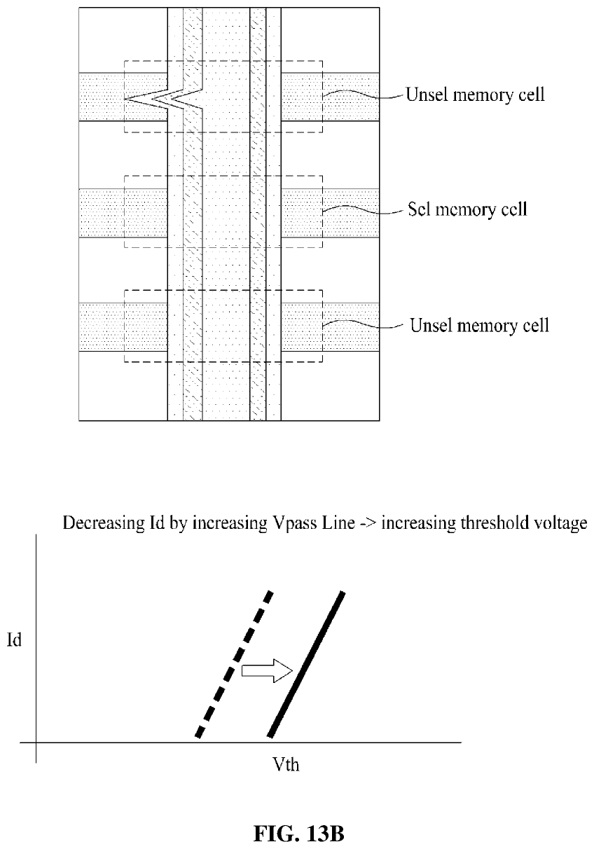

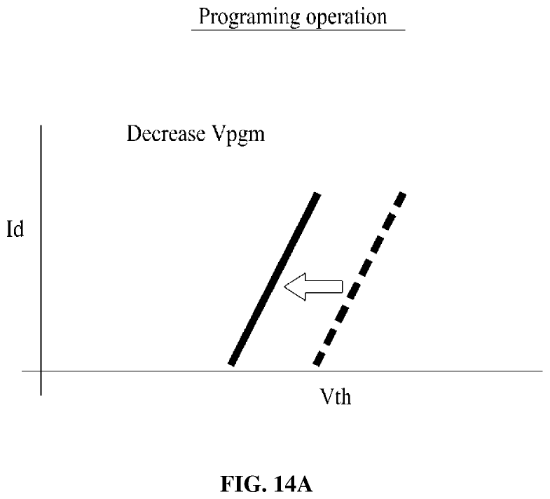

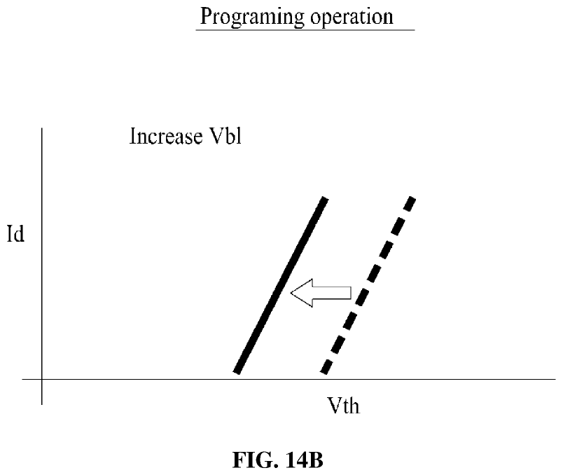

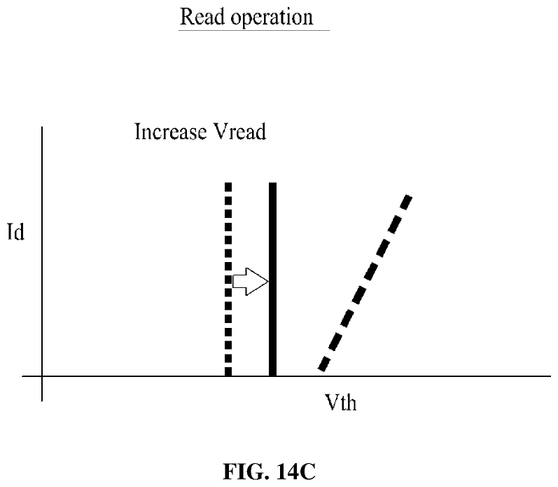

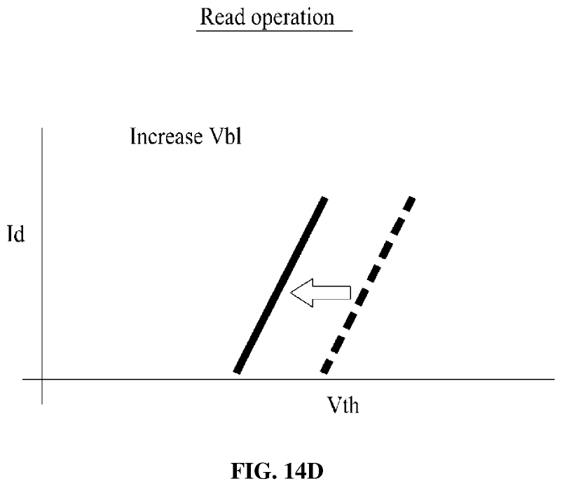

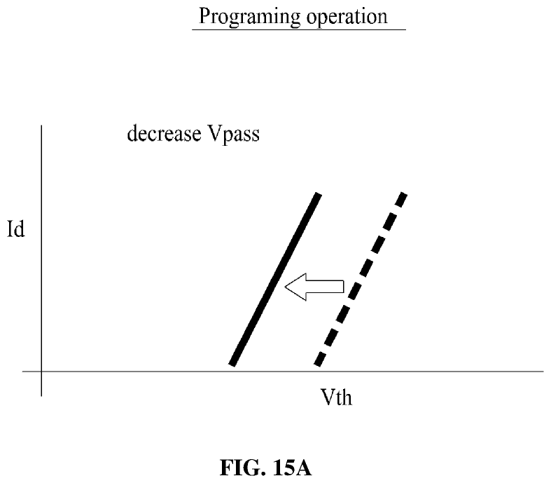

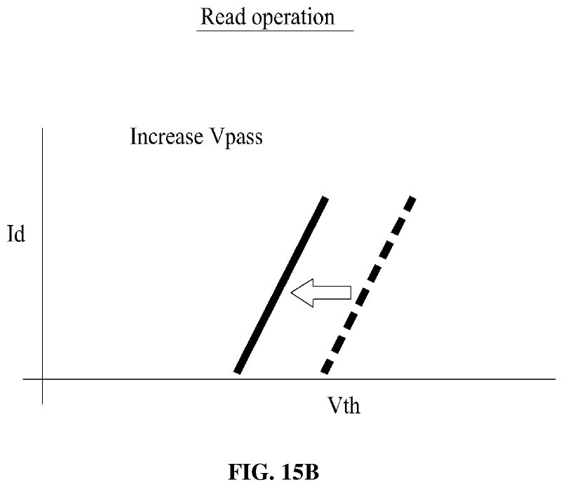

FIG. 11 is a flowchart illustrating a circuit compensating method for improving cell characteristic deterioration caused by an abnormal shape of a vertical channel structure, according to an embodiment. FIG. 12 is a block diagram showing a circuit compensating system that performs the circuit compensating method shown in FIG. 11. FIGS. 13A and 13B are diagrams for describing that an abnormal shape occurs in a vertical channel structure in the 3D flash memory shown in FIG. 9. FIGS. 14A to 14D are diagrams for describing that circuit compensation is performed when a memory cell in which an abnormal shape occurs is a selected memory cell that is the target of a program operation. FIGS. 15A and 15B are diagrams for describing that a circuit compensating method is performed when a memory cell in which an abnormal shape occurs is an unselected memory cell.

The circuit compensating method shown in FIG. 11 may be performed through steps S1110 to S1130 by a circuit compensating system 1200 shown in FIG. 12. To this end, as shown in FIG. 12, the circuit compensating system 1200 may include a database 1210, a monitoring unit 1220, a check unit 1230, and a compensation unit 1240. The components of the circuit compensating system 1200 may be expressions of different functions of a processor performed by a processor according to instructions provided by program codes. For example, the monitoring unit 1220 may be used as a functional expression for monitoring the threshold voltage characteristics of each memory cell. Accordingly, the circuit compensating system 1200 may be implemented as a processor configured to process instructions of a computer program by performing basic arithmetic, logic, and input/output operations.

Before step S1110, the database 1210 may be built and maintained in advance to predict the relationship between the abnormal shape AS of the vertical channel structure VS and threshold voltage characteristics. For example, the database 1210 may measure the threshold voltage characteristics of each of memory cells included in the 3D flash memory structure described with reference to FIGS. 8 to 10 before, after, and during the memory operation, may collect information about an abnormal shape of each of the vertical channel structures VS included in the 3D flash memory, and then may learn the relationship between the abnormal shape AS of the vertical channel structure VS and the threshold voltage characteristics. As a learning method, a previously well-known machine learning algorithm may be used.

Here, the threshold voltage characteristics may include a threshold voltage value of each of the memory cells, a threshold voltage slope of each of the memory cells, and a cell current value of each of the memory cells.

In step S1110, the monitoring unit 1220 may monitor the threshold voltage characteristics of each of the memory cells.

In step S1120, the check unit 1230 may identify at least one memory cell, in which the abnormal shape AS occurs, from among the memory cells based on the threshold voltage characteristics of each of the memory cells by using the database 1210.

When at least one memory cell, in which the abnormal shape AS occurs, is a selected memory cell that is the target of a program operation as shown in FIG. 13A, the threshold voltage of the at least one memory cell, in which the abnormal shape AS occurs, may be increased by strengthening the local field in at least one memory cell in which the abnormal shape AS occurs. When at least one memory cell, in which the abnormal shape AS occurs is an unselected memory cell excluding the selected memory cell that is the target of the program operation, from among the memory cells as shown in FIG. 13B, the cell current of at least one memory cell, in which the abnormal shape AS occurs, decreases as the pass voltage line of at least one memory cell in which the abnormal shape AS occurs increases, thereby increasing a threshold voltage.

Accordingly, in step S1130, the compensation unit 1240 may perform circuit compensation in different ways based on whether at least one memory cell, in which the abnormal shape AS occurs, is a selected memory cell.

In other words, in step S1130, the compensation unit 1240 may distinguish between a case, where at least one memory cell in which the abnormal shape AS occurs is a selected memory cell, and a case where at least one memory cell in which the abnormal shape AS occurs is an unselected memory cell, and may perform circuit compensation.

In more detail, the compensation unit 1240 may distinguish between a case, where at least one memory cell in which the abnormal shape AS occurs is a selected memory cell, and a case where at least one memory cell in which the abnormal shape AS occurs is an unselected memory cell, and may perform circuit compensation by controlling a voltage applied in a program operation or a voltage applied in a read operation on the selected memory cell.

In this case, the circuit compensation may be achieved such that the at least one memory cell, in which the abnormal shape AS occurs, has the same threshold voltage characteristics as the threshold voltage characteristics of another memory cell in which the abnormal shape AS does not occur. For example, the compensation unit 1240 may control a voltage applied during a program operation or a voltage applied in a read operation for the selected memory cell such that at least one memory cell has the same threshold voltage characteristics as the threshold voltage characteristics of another memory cell in which the abnormal shape AS does not occur.

When the at least one memory cell in which the abnormal shape AS occurs is a selected memory cell, the circuit compensation operation of the compensation unit 1240 may be performed as shown in four examples below.

For example, when at least one memory cell in which the abnormal shape AS occurred is a selected memory cell, as shown in FIG. 14A, the compensation unit 1240 may perform circuit compensation that allows the threshold voltage characteristics of at least one memory cell, in which the abnormal shape AS occurs, to be the same as the threshold voltage characteristics of another memory cell in which the abnormal shape AS does not occur, by reducing a program voltage Vpgm applied to the selected memory cell during a program operation.

For another example, when at least one memory cell in which the abnormal shape AS occurs is a selected memory cell, as shown in FIG. 14B, the compensation unit 1240 may reduce the threshold voltage of at least one memory cell in which the abnormal shape AS occurs, by increasing a bit line voltage Vbl applied to the bit line BL of the vertical channel structure VS including the selected memory cell during a program operation. Accordingly, the circuit compensation may be performed such that the threshold voltage characteristics of at least one memory cell in which the abnormal shape AS occurs are the same as the threshold voltage characteristics of another memory cell in which the abnormal shape AS does not occur.

For still another example, when at least one memory cell in which the abnormal shape AS occurs is a selected memory cell, as shown in FIG. 14C, the compensation unit 1240 may perform circuit compensation by increasing a sensing voltage Vread applied to the selected memory cell during a read operation.

For another example, when at least one memory cell in which the abnormal shape AS occurs is a selected memory cell, as shown in FIG. 14D, the compensation unit 1240 may perform circuit compensation by increasing the bit line voltage Vbl applied to the bit line BL of the vertical channel structure VS including the selected memory cell during a read operation.

When the at least one memory cell in which the abnormal shape AS occurs is an unselected memory cell, the circuit compensation operation of the compensation unit 1240 may be performed as shown in two examples below.

For example, when at least one memory cell in which the abnormal shape AS occurred is an unselected memory cell, as shown in FIG. 15A, the compensation unit 1240 may perform circuit compensation by reducing a pass voltage Vpass applied to the at least one memory cell, in which the abnormal shape AS occurs and which corresponds to the unselected memory cell, during a program operation.

For another example, when at least one memory cell in which the abnormal shape AS occurs is an unselected memory cell, as shown in FIG. 15B, the compensation unit 1240 may perform circuit compensation by increasing the pass voltage Vpass applied to the at least one memory cell in which the abnormal shape AS occurs and which corresponds to the unselected memory cell, during a read operation.

The circuit compensating method and system according to one embodiment may improve the cell characteristic deterioration caused by the abnormal shape AS of the vertical channel structure VS through the circuit compensation, and thus may solve problems such as deteriorating memory reliability, accelerating pass voltage disturbances during program and read operations, and reducing a channel current without changing the physical structure.

While embodiments have been shown and described with reference to the accompanying drawings, it will be apparent to those skilled in the art that various modifications and variations may be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

1. A multi-level implementing method in a 3D flash memory, the method comprising:
securing a threshold voltage distribution region by narrowing a distribution of an erase threshold voltage during an erase operation of the 3D flash memory; and
setting multi-level program threshold voltages in the secured threshold voltage distribution region.

2. The method of claim 1, wherein the securing includes:
applying an initial erase voltage to a selected word line corresponding to a memory cell that is a target of the erase operation among a plurality of word lines included in the 3D flash memory;
applying a read voltage to the selected word line; and
applying an additional erase voltage to the selected word line.

3. The method of claim 2, wherein the applying of the read voltage and the applying of the additional erase voltage are sequentially repeated at least once or more.

4. The method of claim 3, wherein the additional erase voltage decreases as the applying of the read voltage and the applying of the additional erase voltage are sequentially repeated.

5. The method of claim 2, wherein the additional erase voltage has a value smaller than the initial erase voltage.

6. A circuit compensating method for improving cell characteristic deterioration caused by an abnormal shape of a vertical channel structure, in a 3D flash memory including word lines formed to extend in a horizontal direction and spaced in a vertical direction, and vertical channel structures configured to penetrate the word lines and formed to extend in the vertical direction, wherein each of the vertical channel structures includes a vertical channel pattern formed to extend in the vertical direction and data storage patterns formed in contact with an outer sidewall of the vertical channel pattern, and each of the vertical channel structures constitutes memory cells corresponding to the word lines, the method comprising:
monitoring a threshold voltage characteristic of each of the memory cells;
identifying at least one memory cell, in which the abnormal shape occurs, from among the memory cells based on the threshold voltage characteristic of each of the memory cells by using a database configured to predict a relationship between an abnormal shape of the vertical channel structure and the threshold voltage characteristic; and
distinguishing between a case where the at least one memory cell is a selected memory cell that is a target of a program operation, and a case where the at least one memory cell is an unselected memory cell excluding the selected memory cell among the memory cells, and performing circuit compensation.

7. The method of claim 6, wherein the performing includes:
distinguishing between the case, where the at least one memory cell is the selected memory cell, and the case where the at least one memory cell is the unselected memory cell, and controlling a voltage applied in the program operation or a voltage applied in a read operation on the selected memory cell.

8. The method of claim 7, wherein the controlling includes:
controlling the voltage applied in the program operation or the voltage applied in the read operation on the selected memory cell such that the at least one memory cell has a threshold voltage characteristic the same as the threshold voltage characteristic of another memory cell in which the abnormal shape does not occur.

9. The method of claim 7, wherein the controlling includes at least one of:
when the at least one memory cell is the selected memory cell:
decreasing a program voltage applied to the selected memory cell during the program operation; or
increasing a bit line voltage applied to a bit line of a vertical channel structure including the selected memory cell during the program operation.

10. The method of claim 7, wherein the controlling includes at least one of:
when the at least one memory cell is the selected memory cell;
increasing a sensing voltage applied to the selected memory cell during the read operation on the selected memory cell; or
increasing a bit line voltage applied to a bit line of a vertical channel structure including the selected memory cell during the read operation.

11. The method of claim 7, wherein the controlling includes:
when the at least one memory cell is the unselected memory cell, decreasing a pass voltage applied to the at least one memory cell during the program operation.

12. The method of claim 7, wherein the controlling includes:
when the at least one memory cell is the unselected memory cell, increasing a pass voltage applied to the at least one memory cell during the read operation on the selected memory cell.

13. The method of claim 6, wherein the threshold voltage characteristic includes a threshold voltage value of each of the memory cells and a cell current value of each of the memory cells.

14. A circuit compensating system for improving cell characteristic deterioration caused by an abnormal shape of a vertical channel structure, in a 3D flash memory including word lines formed to extend in a horizontal direction and spaced in a vertical direction, and vertical channel structures configured to penetrate the word lines and formed to extend in the vertical direction, wherein each of the vertical channel structures includes a vertical channel pattern formed to extend in the vertical direction and data storage patterns formed in contact with an outer sidewall of the vertical channel pattern, and each of the vertical channel structures constitutes memory cells corresponding to the word lines, the system comprising:
a database built and maintained to predict a relationship between the abnormal shape of the vertical channel structure and a threshold voltage characteristic;
a monitoring unit configured to monitor a threshold voltage characteristic of each of the memory cells;
a check unit configured to identify at least one memory cell, in which the abnormal shape occurs, from among the memory cells based on the threshold voltage characteristic of each of the memory cells by using the database; and
a compensation unit configured to distinguish between a case where the at least one memory cell is a selected memory cell that is a target of a program operation, and a case where the at least one memory cell is an unselected memory cell excluding the selected memory cell among the memory cells, and to perform circuit compensation.
